(19) United States
(12) Patent Application Publication
(10) Pub. No.: US 2008/0242089 A1
(43) Pub. Date: Oct. 2, 2008

(54) Method for Distributed Processing at Copper CMP

(75) Inventors: Brian E. Zinn, Allen, TX (US); Rashmi Patil, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/694,157

(22) Filed: Mar. 30, 2007

(51) Int. Cl. H01L 21/461

(52) U.S. Cl. 438/692

(57) ABSTRACT

A method of manufacturing a semiconductor device. A first thickness of a copper layer located over a semiconductor substrate is removed by chemical-mechanical polishing (CMP) on a first platen using a first polishing slurry. The copper layer is located over a barrier layer. A remaining thickness of the copper layer is removed on a second platen using a second polishing slurry. A portion of the barrier layer on the second platen is removed using a third polishing slurry. The third polishing slurry has a substantially different composition from the second polishing slurry.

### TECHNICAL FIELD

The invention is directed to chemical-mechanical polishing (CMP), and in particular, to CMP of a copper layer on a semiconductor wafer.

### BACKGROUND

Chemical-mechanical polishing (CMP) is widely used in integrated circuit manufacturing to form copper interconnects. Interconnects may be vertical (vias) or horizontal (lines). In the copper damascene process, copper is typically electroplated into holes or trenches that have been formed in a dielectric layer on a semiconductor wafer. The electroplating process results in a layer of copper formed over the surface of the dielectric. The layer is removed by polishing, which also separates copper features defined by the holes or trenches to form the interconnects. When a copper polishing step is used to form vias and lines simultaneously, the process is referred to as “dual damascene.” When one polishing step is used to form the vias, and another is used to form lines, the process is referred to as “single damascene.”

The CMP process typically is performed on a process tool that includes several platens, each having a polishing pad fixed thereto. A wafer is placed face down on the polishing pad, and a polishing slurry is dispensed as the platen rotates. Material is removed from the surface in a manner that reduces the height of surface topography. The polishing step may be terminated when a predetermined thickness of material is removed, or when the surface of the wafer undergoes a change in optical reflectivity that can be detected by an end-point system.

In the copper damascene process, the copper layer is removed on a platen set up for copper removal only. A barrier layer and a portion of the dielectric layer underlying the copper layer are removed on a second platen set up for that purpose. Because the removal of the copper layer requires significantly more time than removal of the barrier layer and dielectric portion, the second platen is idle for some of the time required to remove the copper layer on the first platen. This idle time represents wasted processing time and results in lower tool throughput than would be the case if the second platen were used more continuously. This wasted time results in increased cost per wafer in a fiercely competitive industry.

Accordingly, what is needed in the art is a method of polishing semiconductor wafers that reduces the idle time of polishing platens on the polishing tool.

### SUMMARY

To address the above-discussed deficiencies of the prior art, the invention provides, in one aspect, a method of manufacturing a semiconductor device. The method includes removing a first thickness of a copper layer located over a semiconductor substrate by chemical-mechanical polishing. The copper layer is located over a barrier layer. The removing is conducted on a first platen using a first polishing slurry. A remaining thickness of the copper layer is removed on a second platen using a second polishing slurry. A portion of the barrier layer on is removed on the second platen using a third polishing slurry. The third polishing slurry has a substantially different composition from the second polishing slurry.

Another embodiment is a method of manufacturing a semiconductor device. A first thickness of a copper layer located on a semiconductor substrate is removed by chemical-mechanical polishing conducted on a first platen using a first polishing slurry that includes colloidal silica particles. The copper layer is located over a barrier layer. The semiconductor substrate is transferred to a second platen after removing the first thickness. After transferring to the second platen, a remaining thickness of the copper layer is removed on the second platen using the first polishing slurry. The barrier layer and a portion of a dielectric layer underlying the barrier layer are also removed on the second platen using a second polishing slurry having a composition substantially different from that of the first polishing slurry. The colloidal silica particles are dispersed in the first slurry and remain substantially dispersed within the second polishing slurry when mixed therewith on the second platen. Further, a residence time of the semiconductor substrate with respect to the first platen is about equal to a residence time of the semiconductor substrate with respect to the second platen.

Another embodiment is a semiconductor device. The device has transistors formed on a substrate and a dielectric layer formed over the transistors. Interconnects are formed within the dielectric layer and configured to connect the transistors to other circuit components located on the substrate. The interconnects are formed by forming trenches in said dielectric layer. A barrier layer is deposited on a sidewall of the trenches and on a surface of the dielectric layer parallel to the substrate. Copper is placed over the barrier layer, where the placing forms a layer of copper parallel to the substrate. A first thickness of the copper layer is removed by chemical-mechanical polishing on a first platen using a first polishing slurry. A remaining thickness of the copper layer is removed on a second platen using a second polishing slurry having a composition substantially different from that of the first polishing slurry. The barrier layer parallel to the substrate is removed on the second platen using a third polishing slurry.

### BRIEF DESCRIPTION OF THE DRAWINGS

Reference is now made to the following descriptions taken in conjunction with the accompanying drawings, in which:

FIGS. 1A through 1G illustrate a semiconductor device at various stages of manufacturing;

FIGS. 2 through 4 illustrate aspects of a polishing process; and

FIG. 5 illustrates a semiconductor device.

### DETAILED DESCRIPTION

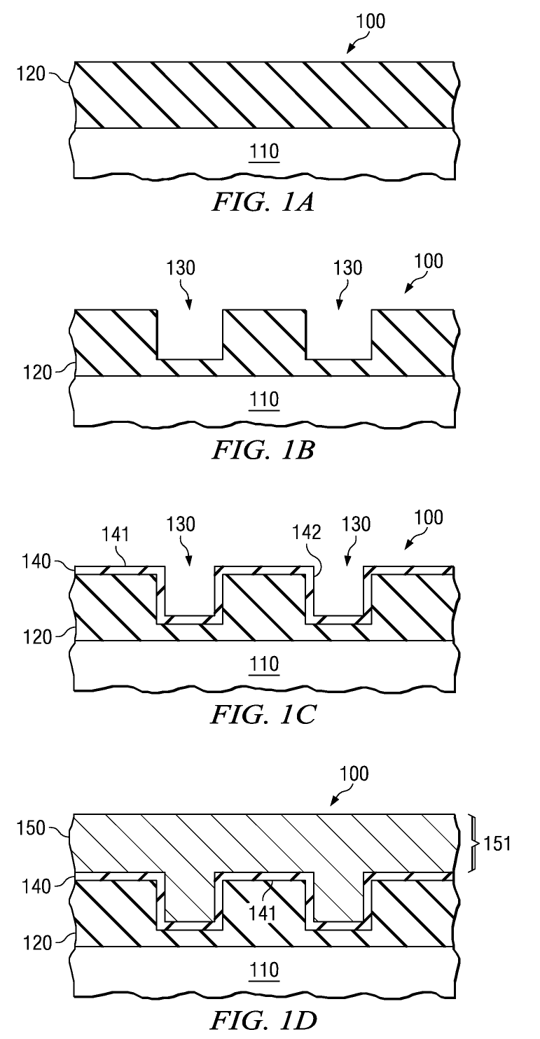

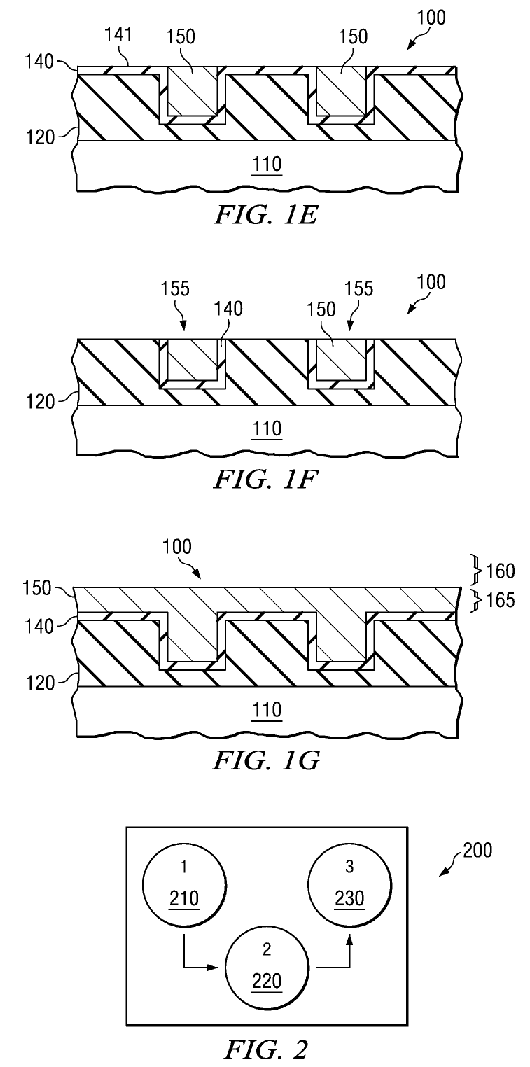

FIG. 1A illustrates a semiconductor device 100 at an early stage of forming an interconnect level. The semiconductor device 100 includes a substrate 110 and a dielectric layer 120. The substrate 110 includes a semiconductor substrate, active or passive electrical components formed thereon, and any previous interconnect levels. The semiconductor substrate may include any type of semiconductor, including silicon, GaAs, SiGe, Ge, and semiconductor-on-insulator (SOI). The substrate 110 may be a wafer, and for brevity used interchangeably as such in the following discussion.

Previous interconnect levels may include contacts, vias and metal lines formed by any process. Examples include tungsten contacts, aluminum or copper vias, and aluminum or copper lines. The dielectric layer 120 may be homogeneous or heterogeneous, and may include any conventional or future discovered dielectric material.

FIG. 1B illustrates trenches 130 formed in the dielectric layer 120. The trenches 130 may be formed by any currently existing or future developed process. In some cases, the trenches 130 are formed by patterning of a resist layer followed by a plasma etch process. The trenches 130 may be associated with a vertical interconnect level, a horizontal interconnect level, or both.

FIG. 1C illustrates a barrier layer 140 formed over the surface of the dielectric layer 120. The barrier layer 140 includes a portion 141 parallel to the substrate 110, and a portion 142 lining sidewalls of the trenches 130. The barrier layer 140 may include Ta, TaN or similar materials that may act as a barrier to copper diffusion into the dielectric layer 120.

FIG. 1D illustrates a copper layer 150 formed over the substrate 110. The copper layer 150 may be deposited by electroplating, e.g., and may include a copper seed layer formed over the barrier layer 140. The copper layer 150 has an initial thickness 151 above the surface of the barrier layer portion 141.

At this point in the manufacturing process, the substrate 110 is polished to remove a portion of the copper layer 150 and the barrier layer 140. FIG. 2 illustrates a CMP process tool 200 configured to perform the polishing. The tool 200 is a non-limiting example of such a process tool for illustration of the described embodiments. In this example, the tool 200 includes three platens, 210, 220, 230. In other cases, the tool may have more or fewer than three platens. A first platen 210 removes copper, and a third platen 230 provides an optional buff polish. In a conventional process, a second platen 220 removes the barrier layer portion 141 and a portion of the dielectric layer 120. In the described embodiments, the second platen 220 removes both a bulk portion of the copper layer 150 and the barrier layer portion 141.

The incoming semiconductor substrate 110 is initially placed face down in contact with the polishing pad on the first platen 210. In a conventional process, the first platen 210 removes substantially all of a bulk portion of the copper layer 150. The bulk copper removal process uses a first polishing slurry designed to remove copper. Bulk copper is that portion of the copper layer 150 above the barrier layer portion 141 that is sufficiently distant from the barrier layer portion 141 to be free of interfacial effects such as alloying and interdiffusion of the barrier material. “Substantially all” means about 90% or greater of the initial thickness 151.

The wafer is then transferred the second platen 220. In the conventional process, a second polishing slurry, substantially different from that of said first polishing slurry, removes any remaining copper, the barrier layer portion 141, and some of the dielectric layer 120 below. The wafer is then transferred to the third platen 230. A third polishing slurry may optionally be used to buff the wafer to remove potential sources of defects, such as scratches and organic residue.

FIG. 1E illustrates the semiconductor device 100 after the initial thickness 151 has been conventionally removed. Thus, only one type of polishing slurry is used on the platen that performed the polish. When a predetermined thickness of copper is removed, or when the barrier layer portion 141 is exposed, the wafer is transferred to another platen in the conventional process for the removal of the portion 141.

FIG. 1F illustrates the semiconductor device 100 after the barrier layer portion 141 has been removed. The removing has isolated the copper remaining in the trenches to form interconnects 155. Such removal may be performed on the second platen 220, e.g.

In a conventional copper CMP process, bulk copper removal and barrier removal are generally not performed on the same platen. In the past, a slurry designed for copper removal was used that included a carrier fluid with an acidic pH (less than about 6). The slurry includes a carrier fluid and may additionally include abrasive particles. The abrasive particles may include particles of a ceramic such as silica, alumina or titania. The precise composition of polishing slurries is generally proprietary, but in general may include pH buffers, surfactants and corrosion inhibitors.

Copper polishing slurries used in prior art processes typically included fused silica particles as the abrasive. In such a slurry, the acidic pH is necessary in part to maintain dispersion of slurry particles suspended in the slurry. When the pH exceeds a value, typically in the neutral range (pH=7), the silica particles tend to form aggregates. Aggregates may cause scratches and particle defects on the semiconductor substrate, reducing product yield and increasing manufacturing costs.

Moreover, the slurry used for barrier removal includes a carrier fluid that is typically basic, with a pH greater than about 8. If the acidic copper removal slurry and the barrier removal slurry are mixed, the silica abrasive in the copper slurry will generally aggregate. Thus, copper and barrier removal are strictly limited to different platens in prior art copper CMP processes.

Recent developments in copper polishing slurry compositions include replacing fused silica particles with colloidal silica for improved uniformity of particle size. In addition, the colloidal silica particles are chemically treated to enable the particles to remain substantially dispersed at a pH higher than about 6 to 7. Particles are substantially dispersed when a significant majority of the particles are not bound to other particles by covalent, ionic or van der Waals forces. A significant majority may in some cases be greater than 95%, and may be greater than 99%.

The invention recognizes for the first time that these recent advances in slurry composition can be exploited to improve throughput of a copper CMP process. Because treated colloidal silica particles remain substantially dispersed as isolated particles at a higher pH than the fused silica particles used in earlier copper polishing slurries, the slurries may both be used sequentially on the same platen to remove a portion of the copper layer 150 and the barrier layer portion 141.

When copper and barrier removal are combined on a single platen, a degree of freedom in the CMP process advantageously results. A portion of the copper removal process load may then be transferred from the first platen 210 to the second platen 220. In this manner, the polishing load on the first platen 210 and the second platen 220 can be made more equal. Thus, idle time of the second platen is reduced, resulting in greater efficiency.

FIG. 1G illustrates an embodiment in which only a first thickness 160 of the copper layer 150 has been removed on the first platen 210, leaving a remaining thickness 165. In this embodiment, the remaining thickness 165 and the barrier layer portion 141 are removed on the same platen, such as the second platen 220, e.g., by successively using two slurries having substantially different compositions.

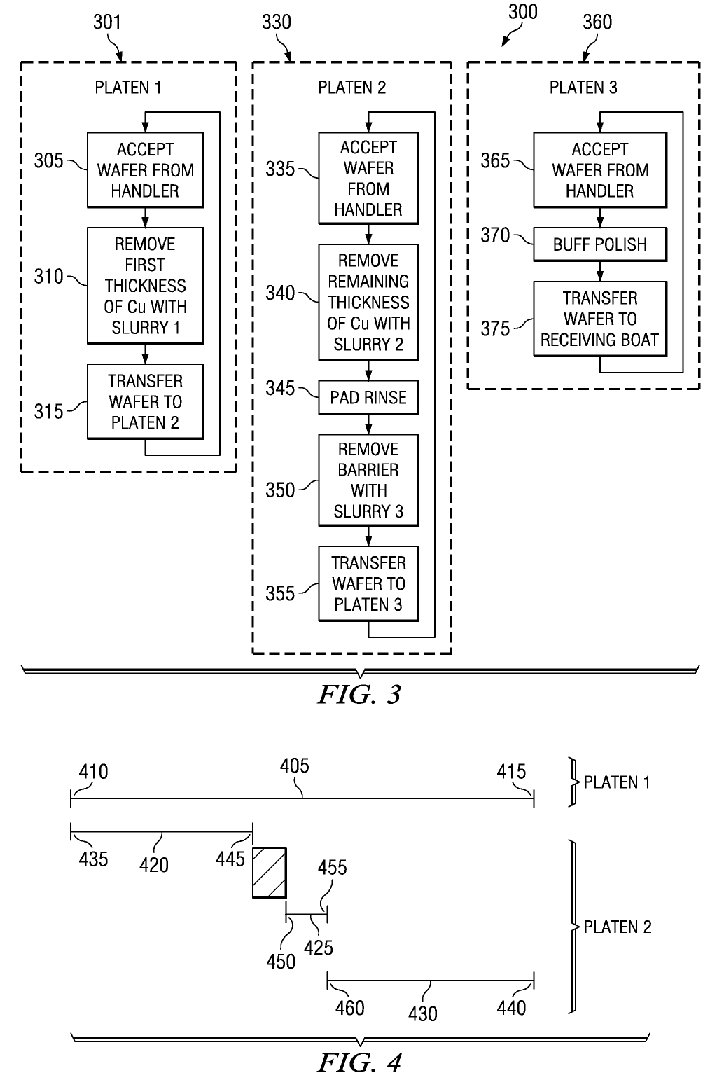

FIG. 3 illustrates a polishing process 300 according to the invention. The process 300 includes parallel subprocesses 301, 330, 360. The subprocess 301 describes the removal of copper on platen 1. The subprocess 330 describes the removal of copper and barrier on platen 2. The subprocess 360 describes an optional buff polish on platen 3. While the process 300 describes a three-platen polishing process, the invention may be practiced using CMP processes with fewer or more platens according to the broad principles described herein.

The subprocess 301 removes the first thickness 160 of the copper layer 150. In a step 305, a wafer from a process lot is provided to the first platen 210. The first platen 210 includes a suitable polishing pad, such as a polyurethane pad. Such pads are well known to those skilled in the art, and are available from multiple equipment vendors. In a step 310, a first polishing slurry is used to remove the first thickness 160. In a step 315, the subprocess 301 transfers the wafer to the second platen 220 for removal of the remaining thickness 165. After transfer of the wafer, the subprocess 301 returns to the step 305 to accept another wafer for processing if any remain in the process lot.

The first thickness 160 of the copper layer 150 is substantially less than the initial thickness 151. In one aspect, the first thickness 160 ranges from about 50% to about 90% of the thickness 151. In another aspect, the first thickness 160 is the amount of copper removed by the subprocess 301 in the time that the subprocess 330 removes the remaining thickness 165 and the barrier layer portion 141. In some cases, the first thickness 160 ranges from about 60% to about 75% of the initial thickness 151.

Referring to the subprocess 330, in a step 335, the wafer is accepted from the subprocess 301. In a step 340, the remaining thickness 165 of copper is removed using a second slurry. In some cases, the first slurry and the second slurry have a different composition. Differences may include, but are not limited to pH, concentration of solids and abrasive composition or size distribution. In other cases, the first slurry and the second slurry have a substantially comparable composition.

The compositions of the first and second slurries are substantially comparable when they are provided by a source that provides the same nominal slurry composition. For example, when the first and second slurries are drawn from the same or different reservoirs of slurry represented by the same vendor part number, the slurries are substantially comparable. However, transient or local variations in slurry composition may occur due to mixing effects, settling of solids, etc. without departing from substantial comparability. The first and second slurries are also substantially comparable when, regardless of their sources, the solids concentration, pH, additives and abrasive are each substantially the same in each slurry.

In a step 345, an optional pad rinse may be performed. If done, the pad rinse may act to flush abrasive particles provided by the first slurry from the polishing pad. This rinse may also dilute the carrier fluid provided by the first slurry. In some cases, the wafer may remain in contact with the polishing pad during the rinse. In other cases, the wafer may be removed from contact with the pad during the step 345.

In a step 350, the wafer is placed in contact with the polishing pad if it was removed during the step 345. The barrier layer portion 141 and a portion of the dielectric layer 120 are removed using a third polishing slurry. The third polishing slurry has a composition substantially different from that of the second polishing slurry. After the barrier layer portion 141 is removed in the step 350, the wafer is transferred to the third platen 230 in a step 355.

The third polishing slurry is substantially different when a characteristic of one or more of the components of the third polishing slurry differs significantly from the same characteristic of the one or more components of the second polishing slurry. Nonlimiting examples include: pH of the carrier fluid; atomic makeup of abrasive particles; average size or size distribution of the abrasive particles; and any stabilizers, corrosion inhibitors or surfactants.

In one aspect, the second and the third polishing slurries have a different pH. In some cases, the pH differs by at least 1 pH unit. In other cases, the pH of the second polishing slurry ranges from about 6.8 to about 7.3, and the pH of the third polishing slurry ranges from about 8.5 to about 10.5.

When the third slurry is dispensed onto the polishing pad, residual slurry particles from the second slurry may remain embedded in the pad or suspended in residual carrier fluid from the second polishing slurry. The residual slurry particles or the residual carrier fluid may mix with the third slurry on the pad. Although the second and the third polishing slurries have a substantially different composition, any residual slurry particles from the second polishing slurry remain substantially dispersed in the third slurry.

Without limitation by theory, it is thought that the chemical treatment of the slurry particles enables their suspension in spite of the carrier fluid having a higher pH than previous copper polishing slurries. It is further thought that this surface treatment enables the abrasive particles to remain suspended at the higher pH of the carrier fluid of the third slurry. Without this recent advance in the copper slurry composition, the slurry particles would tend to form aggregates as previously described.

Thus, while experience in the CMP arts would firmly guide one of ordinary skill to prevent mixing of the second and third slurries, the discovery that these particles remain suspended when mixed as described in the process 300 provides the ability to shift some of the copper removal burden from the first platen 210 to the second platen 220. A residence time of the wafer with respect to the first platen 210 and the second platen 220 may thereby be made about equal. Because the copper removal step is often the rate-limiting step of the copper CMP process, the overall throughput of the process is improved when the residence time is balanced between the first and second platens.

Referring to the subprocess 360, the optional buff polish may be performed after barrier removal. However, the subprocess 360 is not necessary to practice the embodiments described herein. When used, a step 365 accepts the wafer from the subprocess 330. In a step 370, the wafer is placed in contact with a polish pad on the third platen 230. The wafer surface remains in contact with the pad while a buff slurry is dispensed onto the pad. The duration of the buff polish is typically less than the residence time of the wafer with respect to the first and the second platens, so the step 370 generally does not limit the throughput of the process 300. In a step 375, the wafer is rinsed and placed in a receiving carrier for later transfer to a following process step.

The concept of residence time is illustrated in FIG. 4. In a timeline 405, a first wafer is placed in contact with the polishing pad on the first platen 210 at a time 410. The wafer is finally removed from the pad at a time 415. The residence time of the first wafer with respect to the first platen 210 is the duration between the time 410 and the time 415. Any intervening interruption of contact of the wafer with the pad is included in the residence time.

The residence time of a second wafer with respect to the second platen 220 is described by timelines 420, 425, 430. The residence time of the second wafer begins at a time 435 when the surface of the wafer is placed in contact with the polishing pad. The residence time ends when the second wafer is finally removed from contact with the pad at a time 440. Remaining bulk copper (the remaining thickness 165, e.g.) is removed between the time 435 and the time 445. In cases for which the step 340 is terminated by end-point detection, the duration of contact of the wafer with the pad may vary due to variations of the remaining thickness 165. In such cases, there may be some uncertainty regarding the duration between the time 435 and the time 445.

The timeline 425 represents the duration of the optional step 345, during which the polishing pad on the second platen 220 is rinsed. The rinse begins at a time 450 and ends at a time 455. During the duration of the timeline 425, the wafer may or may not be in contact with the polishing pad.

The timeline 430 represents the duration of the step 350 during which the barrier layer portion 141 and a portion of the dielectric layer 120 are removed. In the case that the wafer was removed from the pad in the step 345, the wafer is placed again in contact with the pad at a time 460. In the case in which the wafer remained in contact with the pad during the step 345, the flow of the third polishing slurry begins at the time 460. The step 350 ends at the time 440 when the wafer is removed for the final time from the polishing pad.

When the residence time of the first wafer is about equal to the residence time of the second wafer about equal, loss of throughput due to idle platen time is advantageously minimized. The residence times are about equal when they differ by a maximum difference. In some embodiments, the maximum difference is less that about 25% of the longer residence time. In other embodiments, the maximum difference is less that about 10% of the longer residence time. In still other embodiments, the maximum difference is less that about 5% of the longer residence time.

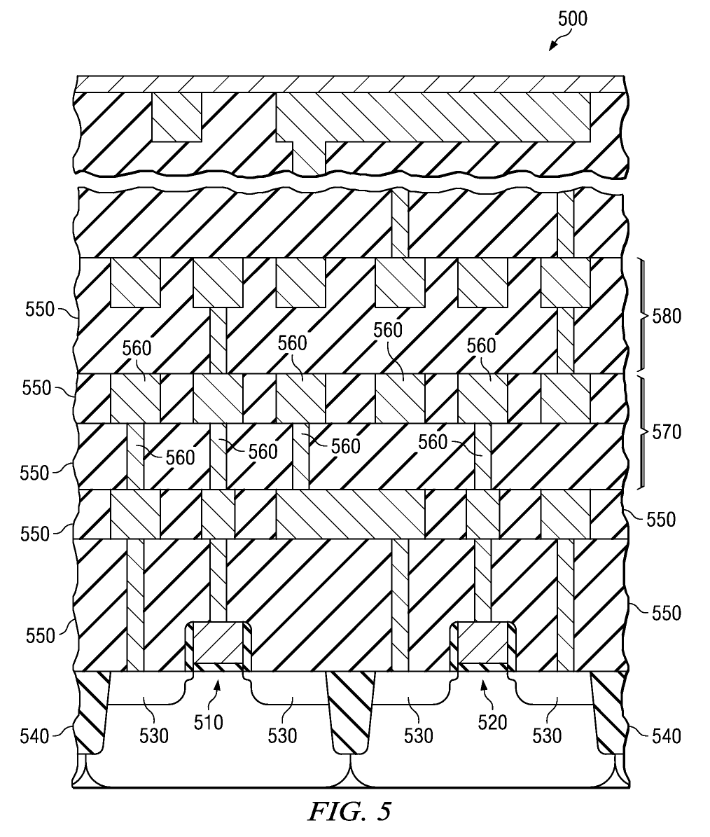

FIG. 5 illustrates a sectional view of a semiconductor device 500 formed according to the invention. The device 500 includes an nMOS transistor 510 and a pMOS transistor 520. The transistors 510, 520 include source/drain regions 530, and are isolated by isolation structures 540. Dielectric layers 550 are formed over the transistors 510, 520, and interconnects 560 are formed therein. The interconnects 560 are configured to connect the transistors to other circuit components, including other transistors operating at a same or different voltage supply or gate voltage.

The interconnects 560 are formed using the process 300 or a similar embodiment. The interconnects 560 may be formed using a single damascene 570 or a dual damascene 580 architecture. The device 500 may include any number of interconnect levels called for by the design of the device 500.

Although the invention has been described in detail, those skilled in the pertinent art should understand that they can make various changes, substitutions and alterations herein without departing from the scope of the invention in its broadest form.

What is claimed is:

1. A method of manufacturing a semiconductor device, comprising:
removing a first thickness of a copper layer located over a semiconductor substrate by chemical-mechanical polishing (CMP) on a first platen using a first polishing slurry, said copper layer being located over a barrier layer;
removing a remaining thickness of said copper layer on a second platen using a second polishing slurry;
removing a portion of said barrier layer on said second platen using a third polishing slurry, wherein said third polishing slurry has a substantially different composition from said second polishing slurry.

2. The method as recited in claim 1, wherein said first thickness ranges from about 60% to about 90% of a total thickness of said copper layer.

3. The method as recited in claim 1, wherein said first and second polishing slurries have a substantially comparable composition.

4. The method as recited in claim 1, wherein a pH of said second polishing slurry ranges from about 6.8 to about 7.3.

5. The method as recited in claim 1, wherein a pH of said third polishing slurry ranges from about 8.5 to about 10.5.

6. The method as recited in claim 1, wherein said second polishing slurry comprises colloidal silica particles.

7. The method as recited in claim 6, wherein said colloidal silica particles are dispersed in said second slurry and remain substantially dispersed within said third polishing slurry on said second platen.

8. The method as recited in claim 1, wherein a residence time of said semiconductor substrate with respect to said first platen is about equal to a residence time of said semiconductor substrate with respect to said second platen.

9. The method as recited in claim 1, wherein a buff polish is performed on a third platen after said removing of a portion of said barrier layer on said second platen.

10. The method as recited in claim 1, wherein said second platen is rinsed with water after said removing of said remaining thickness of copper and before said removing a portion of said barrier layer.

11. A method of manufacturing a semiconductor device, comprising:
removing a first thickness of a copper layer located on a semiconductor substrate by chemical-mechanical polishing (CMP) conducted on a first platen using a first polishing slurry, wherein said first polishing slurry comprises colloidal silica particles, said copper layer being located over a barrier layer;
transferring said semiconductor substrate to a second platen subsequent to removing said first thickness;
removing a remaining thickness of said copper layer on said second platen using said first polishing slurry; and
removing said barrier layer and a portion of a dielectric layer underlying said barrier layer on said second platen using a second polishing slurry having a composition substantially different from that of said first polishing slurry, wherein said colloidal silica particles are dispersed in said first slurry and remain substantially dispersed within said second polishing slurry when mixed therewith on said second platen, and wherein a residence time of said semiconductor substrate with respect to said first platen is about equal to a residence time of said semiconductor substrate with respect to said second platen.

12. The method as recited in claim 11, wherein a pH of said first polishing slurry ranges from about 6.8 to about 7.2.

13. The method as recited in claim 11, wherein a pH of said second polishing slurry ranges from about 8.5 to about 10.5.

14. The method as recited in claim 11, wherein said first thickness ranges from about 60% to about 90% of a total thickness of said copper layer.

15. The method as recited in claim 11, wherein said second platen is rinsed with water after said removing of said remaining thickness of copper and before said removing a portion of said barrier layer.

16. The method as recited in claim 11, wherein a buff polish is performed on a third platen after said removing of a portion of said barrier layer on said second platen.

17. A semiconductor device comprising:
transistors formed on a substrate;
a dielectric layer formed over said transistors; and
interconnects formed within said dielectric layer and configured to connect said transistors to other circuit components located on said substrate, said interconnects formed by:
forming trenches in said dielectric layer;
depositing a barrier layer on a sidewall of said trenches and on a surface of said dielectric layer parallel to said substrate;
placing copper over said barrier layer, said placing forming a layer of copper parallel to said substrate;
removing a first thickness of said copper layer by chemical-mechanical polishing (CMP) on a first platen using a first polishing slurry;
removing a remaining thickness of said copper layer on a second platen using a second polishing slurry having a composition substantially different from that of said first polishing slurry;
removing said barrier layer parallel to said substrate on said second platen using a third polishing slurry.

18. The semiconductor device recited in claim 17, wherein said first and second polishing slurries have a substantially comparable composition.

19. The semiconductor device recited in claim 17, wherein said second polishing slurry comprises colloidal silica particles, and said colloidal silica particles on said second platen remain substantially dispersed within said third polishing slurry.

20. The method as recited in claim 17, wherein a pH of said first polishing slurry ranges from about 6.8 to about 7.2, and a pH of said second polishing slurry ranges from about 8.5 to about 10.5.
